(19) United States
(12) Patent Application Publication
(10) Pub. No.: US 2025/0210572 A1
(43) Pub. Date: Jun. 26, 2025

(54) ADHESIVE FILM FOR SEMICONDUCTORS, INTEGRATED DICING/DIE BONDING FILM AND METHOD FOR PRODUCING SEMICONDUCTOR DEVICE

(71) Applicant: Resonac Corporation, Minato-ku, Tokyo (JP)

(72) Inventor: Yui KUNITO, Minato-ku, Tokyo (JP)

(21) Appl. No.: 18/848,913

(22) PCT Filed: Mar. 17, 2023
(86) PCT No.: PCT/JP2023/010682

§ 371 Date: Sep. 20, 2024

(30) Foreign Application Priority Data
Mar. 25, 2022 (JP) 2022-050022

(51) Int. Cl. H01L 23/00; C09J 5/00; C09J 7/38; H01L 21/683

(52) U.S. Cl. CPC H01L 24/29; C09J 5/00; C09J 7/385; H01L 21/6836; H01L 24/32; H01L 24/83; C09J 2203/326; C09J 2433/00; H01L 24/48; H01L 2224/29191; H01L 2224/32145; H01L 2224/32225; H01L 2224/48227; H01L 2224/8385

(57) ABSTRACT

An adhesive film for a semiconductor contains a thermosetting component, an elastomer, and an inorganic filler. The elastomer contains an acrylic resin having a structural unit derived from a monomer having an aromatic ring. An integrated dicing/die bonding film includes a dicing film and the adhesive film for a semiconductor provided on the dicing film.

### TECHNICAL FIELD

The present disclosure relates to an adhesive film for a semiconductor, an integrated dicing/die bonding film, and a method for producing a semiconductor device.

### BACKGROUND ART

A stacked multi chip package (MCP) having a high capacity by semiconductor chips stacked in multiple stages is widespread. Examples of the stacked MCP include wire-embedded and chip-embedded semiconductor packages. The structure of a semiconductor package in which a wire is embedded by an adhesive film may be referred to as a film over wire (FOW). The structure of a semiconductor package in which a semiconductor chip is embedded by an adhesive film may be referred to as a film over die (FOD). Examples of the semiconductor package in which FOD is adopted include a semiconductor package including a controller chip disposed on the bottom stage, and an adhesive film embedding the controller chip (refer to Patent Literature 1). In the production of the semiconductor package having a FOD or FOW structure, there is a demand for the semiconductor chip or the wire to be sufficiently embedded by the adhesive film.

Recently, in accordance with high integration, a line/space gap of wiring has been narrowed, and such an adhesive film has been required to have excellent highly accelerated temperature and humidity stress test (HAST) resistance. As a method for improving the HAST resistance of the adhesive film, for example, a method using an acrylic resin with a low ratio of a structural unit derived from acrylonitrile is proposed (refer to Patent Literature 2).

### CITATION LIST

### Patent Literature

Patent Literature 1: JP 2014-175459 A
Patent Literature 2: WO 2020/067186 A1

### SUMMARY OF INVENTION

### Technical Problem

However, in the method of the related art, the HAST resistance is improved, but an adhesive force may decrease. Therefore, the adhesive film is required to be capable of making the HAST resistance and the adhesive force compatible.

Therefore, a main object of the present disclosure is to provide an adhesive film for a semiconductor that is excellent in HAST resistance and has a high adhesive force.

### Solution to Problem

According to the studies of the present inventors, it has been found that by using an acrylic resin having a structural unit derived from a monomer having an aromatic ring as an elastomer, it is possible to make the HAST resistance and the adhesive force of the adhesive film for a semiconductor compatible, and the invention of the present disclosure has been completed.

One aspect of the present disclosure relates to an adhesive film for a semiconductor. The adhesive film for a semiconductor (hereinafter, may be simply referred to as an “adhesive film”) contains a thermosetting component, an elastomer, and an inorganic filler. The elastomer contains an acrylic resin having a structural unit derived from a monomer having an aromatic ring.

In one mode, the adhesive film may have a thickness of 60 to 150 μm. In this case, the adhesive film may be an adhesive film for FOD used to cause a semiconductor chip to adhere to a substrate while embedding another semiconductor chip.

In another mode, the adhesive film may have a thickness of 25 to 80 μm. In this case, the adhesive film may be an adhesive film for FOW used to cause a semiconductor chip to adhere to another semiconductor chip while embedding a part or all of a wire connected to the another semiconductor chip.

The elastomer may further contain an acrylic resin not having a structural unit derived from a monomer having an aromatic ring. The weight average molecular weight of the acrylic resin not having a structural unit derived from a monomer having an aromatic ring may be 500000 or more.

The content of the elastomer may be 10 to 60% by mass, on the basis of the total amount of the adhesive film.

The content of the inorganic filler may be 30 to 250 parts by mass, with respect to 100 parts by mass of the thermosetting component.

Another aspect of the present disclosure relates to an integrated dicing/die bonding film. The integrated dicing/die bonding film includes a dicing film, and the adhesive film described above, provided on the dicing film.

Another aspect of the present disclosure relates to a method for producing a semiconductor device. In one mode, the method for producing a semiconductor device includes causing a second semiconductor chip to adhere to a substrate on which a first semiconductor chip is mounted by the adhesive film described above. In this case, the first semiconductor chip is embedded by the adhesive film.

In another mode, the method for producing a semiconductor device includes causing a second semiconductor chip to adhere to a first semiconductor chip by the adhesive film described above. In this case, a part or all of a wire is embedded by the adhesive film.

In one mode or another mode, the first semiconductor chip of the method for producing a semiconductor device may be a controller chip.

The present disclosure includes [1] to [12].

[1] An adhesive film for a semiconductor, containing:
a thermosetting component;
an elastomer; and
an inorganic filler,
in which the elastomer contains an acrylic resin having a structural unit derived from a monomer having an aromatic ring.
   [2] The adhesive film for a semiconductor according to [1],
in which the adhesive film for a semiconductor has a thickness of 60 to 150 μm.
   [3] The adhesive film for a semiconductor according to [1] or [2],
in which the adhesive film for a semiconductor is used to cause a semiconductor chip to adhere to a substrate while embedding another semiconductor chip.
   [4] The adhesive film for a semiconductor according to [1],
in which the adhesive film for a semiconductor has a thickness of 25 to 80 μm.
   [5] The adhesive film for a semiconductor according to [1] or [4],
in which the adhesive film for a semiconductor is used to cause a semiconductor chip to adhere to another semiconductor chip while embedding a part or all of a wire connected to the another semiconductor chip.
   [6] The adhesive film for a semiconductor according to any one of [1] to [5],
in which the elastomer further contains an acrylic resin not having a structural unit derived from a monomer having an aromatic ring, and
a weight average molecular weight of the acrylic resin not having a structural unit derived from a monomer having an aromatic ring is 500000 or more.
   [7] The adhesive film for a semiconductor according to any one of [1] to [6],
in which a content of the elastomer is 10 to 60% by mass, on the basis of a total amount of the adhesive film for a semiconductor.
   [8] The adhesive film for a semiconductor according to any one of [1] to [7],
in which a content of the inorganic filler is 30 to 250 parts by mass, with respect to 100 parts by mass of the thermosetting component.
   [9] An integrated dicing/die bonding film, including:
a dicing film; and
the adhesive film for a semiconductor according to any one of [1] to [8], provided on the dicing film.
   [10]A method for producing a semiconductor device, including
causing a second semiconductor chip to adhere to a substrate on which a first semiconductor chip is mounted by the adhesive film for a semiconductor according to [1] or [2], and
in which the first semiconductor chip is embedded by the adhesive film.
   [11]A method for producing a semiconductor device, including
causing a second semiconductor chip to adhere to a first semiconductor chip by the adhesive film for a semiconductor according to [1] or [4],
in which a wire is connected to the first semiconductor chip, and
a part or all of the wire is embedded by the adhesive film.
   [12] The method for producing a semiconductor device according to [10] or [11],
in which the first semiconductor chip is a controller chip.

### Advantageous Effects of Invention

According to the present disclosure, the adhesive film for a semiconductor that is excellent in the HAST resistance and has a high adhesive force is provided. In addition, according to the present disclosure, the integrated dicing/die bonding film including such an adhesive film for a semiconductor is provided. Further, according to the present disclosure, the method for producing a semiconductor device using such an adhesive film for a semiconductor or integrated dicing/die bonding film is provided.

### BRIEF DESCRIPTION OF DRAWINGS

FIG. 1 is a schematic cross-sectional view illustrating one embodiment of an adhesive film.

FIG. 2 is a schematic cross-sectional view illustrating one embodiment of a stacked body including the adhesive film.

FIG. 3 is a schematic cross-sectional view illustrating one embodiment of the stacked body including the adhesive film.

FIG. 4 is a schematic cross-sectional view illustrating one embodiment of a semiconductor device.

FIG. 5 is an operation flow chart illustrating one embodiment of a method for producing a semiconductor device.

FIG. 6 is an operation flow chart illustrating one embodiment of the method for producing a semiconductor device.

FIG. 7 is an operation flow chart illustrating one embodiment of the method for producing a semiconductor device.

FIG. 8 is an operation flow chart illustrating one embodiment of the method for producing a semiconductor device.

FIG. 9 is an operation flow chart illustrating one embodiment of the method for producing a semiconductor device.

FIG. 10 is a schematic cross-sectional view illustrating another embodiment of the semiconductor device.

FIG. 11 is a schematic cross-sectional view illustrating another embodiment of the semiconductor device.

### DESCRIPTION OF EMBODIMENTS

The present disclosure is not limited to the following examples. In the following examples, constituents (also including steps and the like) thereof are not essential, unless otherwise specified. The size of the constituents in each of the drawings is conceptual, and a relative relationship of the size between the constituents is not limited to that illustrated. The following numerical values and range thereof do not limit the present disclosure.

In this specification, a numerical range represented by using “to” includes numerical values described before and after “to” as the minimum value and the maximum value, respectively. In numerical ranges described in stages in this specification, the upper limit value or the lower limit value described in one numerical range may be replaced with the upper limit value or the lower limit value of a numerical range described in the other stage. In the numerical range described in this specification, the upper limit value or the lower limit value of the numerical range may be replaced with values described in Examples.

In this specification, (meth)acrylate indicates acrylate or methacrylate corresponding thereto. The same also applies to other similar expressions such as (meth)acrylic acid ester, a (meth)acryloyl group, and a (meth)acrylic copolymer.

Only one type of materials exemplified below may be used alone, or two or more types thereof may be used in combination, unless otherwise specified. In a case where there are a plurality of substances corresponding to each component in a composition, the content of each component in the composition indicates the total amount of the plurality of substances in the composition, unless otherwise specified.

### [Adhesive Film for Semiconductor (Adhesive Film)]

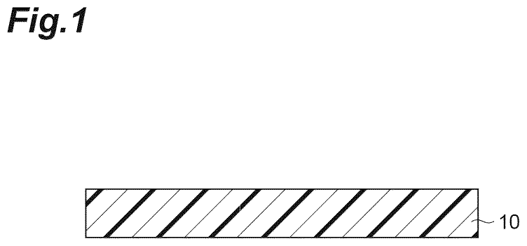

FIG. 1 is a schematic cross-sectional view illustrating one embodiment of an adhesive film. An adhesive film 10 illustrated in FIG. 1 contains a thermosetting component (hereinafter, may be referred to as a “component (A)”), an elastomer (hereinafter, may be referred to as a “component (B)”), and an inorganic filler (hereinafter, may be referred to as a “component (C)”). The adhesive film 10 may contain a curing accelerator (hereinafter, may be referred to as a “component (D)”), a coupling agent (hereinafter, may be referred to as a “component (E)”), other components, and the like, in addition to the component (A), the component (B), and the component (C). The adhesive film 10 can be a film formed from a thermosetting adhesive agent containing the component (A), the component (B), the component (C), and the like. The adhesive film 10 may be in a semi-cured (stage B) state. The adhesive film 10 can be in a cured (stage C) state after a curing treatment.

### Component (A): Thermosetting Component

The component (A) may contain a thermosetting resin (A1) that is a compound having a functional group forming a cross-linked structure by a thermal curing reaction, and may further contain a curing agent (A2) that reacts with a thermosetting resin. The thermosetting resin, from the viewpoint of adhesiveness, may contain an epoxy resin that is a compound having an epoxy group. In this case, the curing agent is a phenol resin that is a compound having a phenolic hydroxyl group.

Examples of the epoxy resin used as the thermosetting resin include a bisphenol A-type epoxy resin; a bisphenol F-type epoxy resin; a bisphenol S-type epoxy resin; a phenol novolac-type epoxy resin; a cresol novolac-type epoxy resin; a bisphenol A novolac-type epoxy resin; a bisphenol F novolac-type epoxy resin; a stilbene-type epoxy resin; a triazine skeleton-containing epoxy resin; a fluorene skeleton-containing epoxy resin; a triphenol methane-type epoxy resin; a biphenyl-type epoxy resin; a xylene-type epoxy resin; a biphenyl aralkyl-type epoxy resin; a naphthalene-type epoxy resin; a diglycidyl ether compound of polycyclic aromatics such as polyfunctional phenols and anthracene, and the like. Only one type of the epoxy resin may be used alone, or two or more types thereof may be used in combination. Among them, the epoxy resin, from the viewpoint of the tackiness and the bendability of the film, may include the cresol novolac-type epoxy resin, the bisphenol F-type epoxy resin, the bisphenol A-type epoxy resin, or a combination thereof.

The epoxy resin may contain a liquid epoxy resin (an epoxy resin with a softening point of 40° C. or lower) that is a liquid in 30° C. That is, the epoxy resin may be a combination of the liquid epoxy resin and a solid epoxy resin (an epoxy resin with a softening point of higher than 40° C.) that is a solid at 30° C. Note that in this specification, the softening point indicates a value measured by a ring-and-ball method, on the basis of JIS K7234. The content of the liquid epoxy resin may be 3 to 15% by mass, on the basis of the total amount of the adhesive film. By the thermosetting resin containing the liquid epoxy resin, there is a tendency that the bendability of the adhesive film is improved. In addition, by combining the liquid epoxy resin and the solid epoxy resin, there is a tendency that the embeddability of a semiconductor chip and a wire is improved.

Examples of a commercially available product of the liquid epoxy resin include EXA-830CRP (Product Name, manufactured by DIC Corporation, a liquid at 30° C.), YDF-8170C (Product Name, manufactured by NIPPON STEEL Chemical & Material Co., Ltd., a liquid at 30° C.), EP-4088S (Product Name, manufactured by ADEKA Corporation, a liquid at 30° C.), and the like.

The epoxy equivalent of the epoxy resin is not particularly limited, and may be 90 to 300 g/eq, or 110 to 290 g/eq. In a case where the epoxy equivalent of the epoxy resin is in such a range, there is a tendency that it is easy to ensure the fluidity of the thermosetting adhesive agent when forming the adhesive film while maintaining the bulk strength of the adhesive film.

Examples of the phenol resin used as the curing agent include a novolac-type phenol resin obtained by the condensation or cocondensation of phenol such as phenol, cresol, resorcine, catechol, bisphenol A, bisphenol F, phenyl phenol, and aminophenol and/or naphthol such as α-naphthol, β-naphthol, and dihydroxynaphthalene, and a compound having an aldehyde group, such as formaldehyde, under an acidic catalyst, a phenol aralkyl resin synthesized from phenols such as allylated bisphenol A, allylated bisphenol F, allylated naphthalene diol, phenol novolac, and phenol and/or naphthols, and dimethoxyparaxylene or bis(methoxymethyl) biphenyl, and a naphthol aralkyl resin. Only one type of the phenol resin may be used alone, or two or more types thereof may be used in combination. The phenol resin may contain a phenyl aralkyl-type phenol resin, a phenol novolac resin, or a combination thereof.

The hydroxyl equivalent of the phenol resin may be 70 g/eq or more, or 70 to 300 g/eq. In a case where the hydroxyl equivalent of the phenol resin is 70 g/eq or more, there is a tendency that the storage modulus of the adhesive film further increases. In a case where the hydroxyl equivalent of the phenol resin is 300 g/eq or less, the occurrence of foam formation and outgasing can be further suppressed.

Examples of a commercially available product of the phenol resin include PSM-4326 (Product Name, manufactured by Gun Ei Chemical Industry Co., Ltd., Softening Point: 120° C.), J-DPP-140 (Product Name, manufactured by JFE Chemical Corporation, Softening Point: 140° C.), GPH-103 (Product Name, manufactured by Nippon Kayaku Co., Ltd., Softening Point: 99 to 106° C.), MEH-7800M (Product Name, manufactured by Meiwa Kasei Co., Ltd., Softening Point: 80° C.), J-DPP-85 (Product Name, manufactured by FE Chemical Corporation, Softening Point: 85° C.), MEH-5100-5S (Product Name, manufactured by Meiwa Kasei Co., Ltd., Softening Point: 65° C.), and the like.

In a case where the thermosetting resin contains the epoxy resin, and the curing agent contains the phenol resin, a ratio (epoxy equivalent:hydroxyl equivalent) of the epoxy equivalent of the epoxy resin to the hydroxyl equivalent of the phenol resin, from the viewpoint of curability, may be 0.30/0.70 to 0.70/0.30, 0.35/0.65 to 0.65/0.35, 0.40/0.60 to 0.60/0.40, or 0.45/0.55 to 0.55/0.45. In a case where the equivalent ratio is 0.30/0.70 or more, there is a tendency that more sufficient curability is obtained. In a case where the equivalent ratio is 0.70/0.30 or less, it is possible to prevent a viscosity from excessively increasing, and obtain more sufficient fluidity.

The softening point of the curing agent may be 50 to 200° C., or 60 to 150° C. There is a tendency that the curing agent with a softening point of 200° C. or lower is likely to have excellent compatibility with the thermosetting resin.

The content of the component (A) (the total content of the thermosetting resin and the curing agent) may be 10% by mass or more, or may be 15% by mass or more, 20% by mass or more, 23% by mass or more, 25% by mass or more, or 30% by mass or more, on the basis of the total amount of the adhesive film. In a case where the content of the component (A) is 10% by mass or more, on the basis of the total amount of the adhesive film, there is a tendency that the adhesive force of the adhesive film is improved. The content of the component (A), from the viewpoint of film moldability, may be 80% by mass or less, 70% by mass or less, 60% by mass or less, 50% by mass or less, or 45% by mass or less, on the basis of the total amount of the adhesive film.

### Component (B): Elastomer

The component (B) may contain an acrylic resin having a structural unit derived from a monomer having an aromatic ring (hereinafter, may be referred to as a “first acrylic resin”), and may further contain an acrylic resin not having a structural unit derived from a monomer having an aromatic ring (hereinafter, may be referred to as a “second acrylic resin”).

The first acrylic resin is an acrylic resin (acrylic rubber) having a structural unit derived from a monomer having a (meth)acryloyl group as a main component. Examples of the monomer having a (meth)acryloyl group include (meth)acrylic acid ester ((meth)acrylate), a (meth)acrylic acid, (meth)acrylonitrile, and the like. The content of the structural unit derived from the monomer having a (meth)acryloyl group, for example, may be 70% by mass or more, 80% by mass or more, or 90% by mass or more, on the basis of the total amount of the structural unit configuring the first acrylic resin. The first acrylic resin may have a structural unit derived from (meth)acrylic acid ester having a cross-linkable functional group such as an epoxy group, an alcoholic or phenolic hydroxyl group, and a carboxyl group. In a case where the first acrylic resin has the structural unit derived from the (meth)acrylic acid ester having a cross-linkable functional group, it is possible to cause a reaction with the component (A) to progress by heating, and improve an adhesive strength after curing.

The first acrylic resin has the structural unit derived from the monomer having an aromatic ring. By the component (B) containing such a first acrylic resin, there is a tendency that the adhesive force of the adhesive film is improved. Examples of the monomer having an aromatic ring include a monomer having an aromatic ring that is a monomer having a (meth)acryloyl group (a monomer having an aromatic ring and having a (meth)acryloyl group), a monomer having an aromatic ring that is a monomer not having a (meth)acryloyl group (a monomer having an aromatic ring and not having a (meth)acryloyl group), and the like.

Examples of the monomer having an aromatic ring and having a (meth)acryloyl group include phenyl (meth)acrylate, benzyl (meth)acrylate, hydroxybenzyl (meth)acrylate, phenoxyethyl (meth)acrylate, hydroxyphenyl (meth)acrylate, a (meth)acryloyl oxyethyl phthalic acid, phenoxypolyethylene glycol (meth)acrylate, ethoxylated nonyl phenyl ether (meth)acrylate, and the like.

Examples of the monomer having an aromatic ring and not having a (meth)acryloyl group include styrene; a styrene derivative such as α-methyl styrene, ethyl styrene, butyl styrene, isobutyl styrene, propyl styrene, isopropyl styrene, fluorostyrene, chlorostyrene, bromostyrene, a styrene sulfonic acid, and hydroxystyrene (vinyl phenol); an aromatic vinyl compound such as vinyl toluene, vinyl pyridine, isopropenyl phenol, allyl phenol, vinyl naphthalene, vinyl anthracene, vinyl phenanthrene, and vinyl pyrene, and a derivative thereof, and the like.

The content of the structural unit derived from the monomer having an aromatic ring may be 1% by mass or more, 3% by mass or more, or 5% by mass or more, and may be 30% by mass or less, 25% by mass or less, or 20% by mass or less, on the basis of the total amount of the structural unit configuring the first acrylic resin.

The glass transition temperature (Tg) of the first acrylic resin may be 0° C. or higher, or may be 3° C. or higher. In a case where Tg of the first acrylic resin is 0° C. or higher, there is a tendency that it is possible to further improve the adhesive strength of the adhesive film, and prevent the bendability of the adhesive film from excessively increasing. Accordingly, it is easy to cut the adhesive film when dicing a wafer, and it is possible to prevent the occurrence of burr. The upper limit of Tg of the first acrylic resin is not particularly limited, and for example, may be 55° C. or lower, 50° C. or lower, 45° C. or lower, 40° C. or lower, 35° C. or lower, 30° C. or lower, or 25° C. or lower. In a case where Tg of the first acrylic resin is 55° C. or lower, there is a tendency that a lamination property to the wafer is improved. Accordingly, the adhesive force is improved, and an effect of preventing chip flying after dicing is improved. In addition, it is possible to prevent chipping during dicing due to a decrease in cohesiveness with a semiconductor wafer. Note that in this specification, the glass transition temperature (Tg) indicates a value measured by using a thermal differential scanning calorimetry (DSC) (for example, manufactured by Rigaku Corporation, Thermo Plus 2). Tg of the first acrylic resin can be adjusted to a desired range by adjusting the type and the content of the structural unit configuring the first acrylic resin.

The weight average molecular weight (Mw) of the first acrylic resin may be 100000 or more, 200000 or more, or 300000 or more, and may be 3000000 or less, 2000000 or less, or 1000000 or less. In a case where Mw of the first acrylic resin is in such a range, it is possible to suitably control film formability, a film strength, flexibility, tackiness, and the like, it is excellent in reflowability, and it is possible to improve the embeddability. Note that in this specification, Mw indicates a value obtained by measurement using a gel permeation chromatography (GPC), and conversion using a calibration curve of standard polystyrene. Note that in GPC, in a case where a plurality of peaks are observed, a weight average molecular weight resulting from a peak with the highest peak strength is defined as the weight average molecular weight in this specification.

The content of the first acrylic resin may be 20 to 100% by mass, on the basis of the total amount of the component (B). In a case where the content of the first acrylic resin is 20% by mass or more, on the basis of the total amount of the component (B), there is a tendency that it is easy to make HAST resistance and the adhesive force of the adhesive film compatible. The content of the first acrylic resin may be 22% by mass or more, or 25% by mass or more, and may be 90% by mass or less, 80% by mass or less, 70% by mass or less, 60% by mass or less, 50% by mass or less, 45% by mass or less, or 40% by mass or less, on the basis of the total amount of the component (B).

The second acrylic resin is an acrylic resin (acrylic rubber) having a structural unit derived from a monomer having a (meth)acryloyl group as a main component, and is an acrylic resin (acrylic rubber) not having a structural unit derived from a monomer having an aromatic ring. That is, the second acrylic resin can be referred to as an acrylic resin (acrylic rubber) excluding the structural unit derived from the monomer having an aromatic ring from the first acrylic resin. The content of the structural unit derived from the monomer having a (meth)acryloyl group, for example, may be 70% by mass or more, 80% by mass or more, or 90% by mass or more, on the basis of the total amount of the structural unit configuring the second acrylic resin. The second acrylic resin may have a structural unit derived from (meth)acrylic acid ester having a cross-linkable functional group such as an epoxy group, an alcoholic or phenolic hydroxyl group, and a carboxyl group. In a case where the second acrylic resin has the structural unit derived from the (meth)acrylic acid ester having a cross-linkable functional group, it is possible to cause the reaction with the component (A) to progress by heating, and improve the adhesive strength after curing.

The glass transition temperature (Tg) of the second acrylic resin may be 5° C. or higher, or may be 8° C. or higher. The upper limit of Tg of the second acrylic resin is not particularly limited, and for example, may be 55° C. or lower, 50° C. or lower, 45° C. or lower, 40° C. or lower, 35° C. or lower, 30° C. or lower, or 25° C. or lower.

The weight average molecular weight (Mw) of the second acrylic resin may be 500000 or more, 600000 or more, or 700000 or more, and may be 3000000 or less, 2000000 or less, or 1000000 or less.

The content of the second acrylic resin may be 0 to 80% by mass, on the basis of the total amount of the component (B). The content of the second acrylic resin may be 78% by mass or less, or 75% by mass or less, and may be 10% by mass or more, 20% by mass or more, 30% by mass or more, 40% by mass or more, 50% by mass or more, 55% by mass or more, or 60% by mass or more, on the basis of the total amount of the component (B).

The first acrylic resin and the second acrylic resin, from the viewpoint of the HAST resistance, may be an acrylic resin with a low ratio of a structural unit derived from (meth)acrylonitrile. The first acrylic resin and the second acrylic resin, for example, may be an acrylic resin satisfying the condition of Expression (1) described below when in an infrared absorption spectrum (an IR spectrum), the area of an absorption peak derived from the stretching vibration of a carbonyl group is set as PA_{CO}, and the area of a peak derived from the stretching vibration of a nitrile group is set as PA_{CN}.

$${PA}_{CN} / {PA}_{CO} \leq 0.1 \qquad ( 1 )$$

Here, the carbonyl group is mainly derived from the (meth)acrylic acid ester that is a structural unit, and the nitrile group is mainly derived from the (meth)acrylonitrile that is a structural unit. Note that the area (PA_{CO}) of the absorption peak derived from the stretching vibration of the carbonyl group and the area (PA_{CN}) of the peak derived from the stretching vibration of the nitrile group, for example, can be calculated by the following method.

First, for a mixture of the first acrylic resin and the second acrylic resin or an adhesive film containing the first acrylic resin and the second acrylic resin, a transmissive IR spectrum is measured by a KBr tablet method, and the spectrum is displayed with an absorbance on a vertical axis and a wave number (cm⁻¹) on a horizontal axis. In the measurement of the IR spectrum, for example, FT-IR6300 (manufactured by JASCO Corporation, Light Source: a high-brightness ceramic light source, Detector: DLATGS) can be used. In the displayed spectrum, when a straight line connecting two points of 1650 cm⁻¹ and 1800 cm⁻¹ on the spectrum is set as a baseline, the area (PA_{CO}) of the absorption peak derived from the stretching vibration of the carbonyl group is defined as the area of an absorbance surrounded by the spectrum and the baseline. When a straight line connecting two points of 2230 cm⁻¹ and 2300 cm⁻¹ on the spectrum is set as a baseline, the area (PA_{CN}) of the peak derived from the stretching vibration of the nitrile group is defined as the area of an absorbance surrounded by the spectrum and the baseline. On the basis of PA_{CO} and PA_{CN} defined as described above, PA_{CN}/PA_{CO} can be calculated.

PA_{CN}/PA_{CO} of the first acrylic resin and the second acrylic resin may be 0.100 or less, 0.090 or less, 0.080 or less, 0.070 or less, 0.060 or less, 0.050 or less, 0.040 or less, 0.030 or less, or 0.020 or less. In a case where PA_{CN}/PA_{CO} is 0.100 or less, since the coagulation force of the acrylic resin decreases, there is a tendency that the embeddability is improved.

The component (B) may contain other elastomers in addition to the first acrylic resin and the second acrylic resin. Examples of the other elastomer include a polyester resin, a polyamide resin, a polyimide resin, a silicone resin, and a butadiene resin; denatured resins thereof, and the like. The content of the other elastomer may be 0 to 20% by mass, on the basis of the total amount of the component (B).

The content of the component (B) may be 10 to 60% by mass, on the basis of the total amount of the adhesive film. In a case where the content of the component (B) is 10% by mass or more, on the basis of the total amount of the adhesive film, there is a tendency that the embeddability of the adhesive film is improved, and in a case where the content is 60% by mass or less, there is a tendency that the adhesive force of the adhesive film is improved. The content of the component (B) may be 15% by mass or more, 20% by mass or more, 25% by mass or more, or 30% by mass or more, and may be 55% by mass or less, 50% by mass or less, 45% by mass or less, 40% by mass or less, or 38% by mass or less, on the basis of the total amount of the adhesive film.

### Component (C): Inorganic Filler

The component (C), for example, may be at least one type selected from aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, and silica. From the viewpoint of adjusting a melt viscosity, the component (C) may contain the silica.

The average particle size of the component (C), from the viewpoint of the fluidity, may be 0.01 μm (10 nm) or more, 0.03 μm (30 nm) or more, 0.05 μm (50 nm) or more, or 0.1 μm (100 nm) or more, and may be 1.5 (1500 nm) m or less, 1.0 μm (1000 nm) or less, 0.8 μm (800 nm) or less, or 0.6 μm (600 nm) or less. Two or more types of components (C) with different average particle sizes may be combined. Here, the average particle size indicates a particle size at a cumulative frequency of 50% in a particle size distribution obtained by a laser diffraction scattering method. Note that the average particle size of the component (C) can also be obtained by using the adhesive film in which the component (C) is contained. In this case, the average particle size of the component (C) can be obtained from a particle size distribution obtained by dispersing a residue, which is obtained by heating the adhesive film to decompose resin components, in a solvent to prepare a dispersion liquid, and applying a laser diffraction scattering method thereto.

The adhesive film may contain a first inorganic filler and a second inorganic filler satisfying the following conditions. By the adhesive film containing the first inorganic filler and the second inorganic filler, it is possible to improve the embeddability, and improve a rupture strength, the adhesive force, and the like after curing.
The average particle size of the first inorganic filler is 300 to 1000 nm.
The average particle size of the second inorganic filler is 0.05 to 0.70 times the average particle size of the first inorganic filler.
The total content of the first inorganic filler and the second inorganic filler (the component (C)) is 10 to 60% by mass, on the basis of the total amount of the adhesive film.

The average particle size of the first inorganic filler is 300 to 1000 nm, may be 350 nm or more, 400 nm or more, or 450 nm or more, and may be 900 nm or less, 800 nm or less, 700 nm or less, or 600 nm or less.

The average particle size of the second inorganic filler may be less than 300 nm, and may be 250 nm or less, 220 nm or less, or 200 nm or less. The average particle size of the second inorganic filler, for example, may be 10 nm or more, 50 nm or more, or 100 nm or more.

The average particle size indicates a particle size at a cumulative frequency of 50% in a particle size distribution obtained by a laser diffraction scattering method. Note that the average particle size of the first inorganic filler and the second inorganic filler can also be obtained by using the adhesive film containing the first inorganic filler and the second inorganic filler. In this case, from a particle size distribution obtained by dispersing a residue, which is obtained by heating the adhesive film to decompose resin components, in a solvent to prepare a dispersion liquid, and applying a laser diffraction scattering method thereto, the numerical value of a peak in a range of 300 to 1000 nm can be set as the average particle size of the first inorganic filler, and the numerical value of a peak in a range less than 300 nm can be set as the average particle size of the second inorganic filler.

The average particle size of the second inorganic filler is 0.05 to 0.70 times the average particle size of the first inorganic filler. The average particle size of the second inorganic filler may be 0.10 times or more, 0.20 times or more, or 0.30 times or more the average particle size of the first inorganic filler, and may be 0.60 times or less, 0.50 times or less, or 0.40 times or less the average particle size of the first inorganic filler.

The content of the first inorganic filler may be 5 to 60% by mass, may be 6% by mass or more, 8% by mass or more, or 10% by mass or more, and may be 55% by mass or less, 45% by mass or less, 40% by mass or less, 35% by mass or less, or 30% by mass or less, on the basis of the total amount of the adhesive film.

The content of the second inorganic filler may be 0 to 40% by mass, may be 3% by mass or more, 5% by mass or more, 10% by mass or more, 12% by mass or more, or 15% by mass or more, and may be 35% by mass or less, 30% by mass or less, or 25% by mass or less, on the basis of the total amount of the adhesive film.

The total content of the first inorganic filler and the second inorganic filler (the component (C)) is 10 to 60% by mass, may be 15% by mass or more, 18% by mass or more, 20% by mass or more, 25% by mass or more, or 30% by mass or more, and may be 55% by mass or less, 52% by mass or less, or 50% by mass or less, on the basis of the total amount of the adhesive film.

A mass ratio of the first inorganic filler to the total of the first inorganic filler and the second inorganic filler (the component (C)) may be 40 to 100% by mass, may be 45% by mass or more, 50% by mass or more, or 55% by mass or more, and may be 95% by mass or less, 90% by mass or less, or 85% by mass or less.

A mass ratio of the second inorganic filler to the total of the first inorganic filler and the second inorganic filler (the component (C)) may be 0 to 60% by mass, may be 5% by mass or more, 10% by mass or more, or 15% by mass or more, and may be 55% by mass or less, 50% by mass or less, or 45% by mass or less.

The content of the component (C) may be 30 to 250 parts by mass, with respect to 100 parts by mass of the component (A) (the total of the thermosetting resin and the curing agent). In a case where the content of the component (C) is in such a range, there is a tendency that the adhesive force of the adhesive film is improved. The content of the component (C) may be 35 parts by mass or more, 40 parts by mass or more, 50 parts by mass or more, or 55 parts by mass or more, and may be 220 parts by mass or less, 200 parts by mass or less, 180 parts by mass or less, 160 parts by mass or less, 150 parts by mass or less, 140 parts by mass or less, 130 parts by mass or less, 120 parts by mass or less, or 100 parts by mass or less, with respect to 100 parts by mass of the component (A) (the total of the thermosetting resin and the curing agent).

### Component (D): Curing Accelerator

Examples of the component (D) include imidazoles and derivatives thereof, an organic phosphorus-based compound, secondary amines, tertiary amines, a quaternary ammonium salt, and the like. Only one type of the component (D) may be used alone, or two or more types thereof may be used in combination. Among them, from the viewpoint of reactivity, the component (D) may be the imidazoles and the derivatives thereof.

Examples of the imidazoles include 2-methyl imidazole, 1-benzyl-2-methyl imidazole, 1-cyanoethyl-2-phenyl imidazole, 1-cyanoethyl-2-methyl imidazole, and the like. Only one type of the imidazoles may be used alone, or two or more types thereof may be used in combination.

### Component (E): Coupling Agent

The component (E) may be a silane coupling agent. Examples of the silane coupling agent include γ-ureidopropyl triethoxysilane, γ-mercaptopropyl trimethoxysilane, 3-phenyl aminopropyl trimethoxysilane, 3-(2-aminoethyl) aminopropyl trimethoxysilane, and the like. Only one type of the silane coupling agent may be used alone, or two or more types thereof may be used in combination.

The adhesive film may further contain other components. Examples of the other component include a pigment, an ion scavenger, an antioxidant, and the like.

The total content of the component (D), the component (E), and the other component may be 0.1% by mass or more, 0.3% by mass or more, or 0.5% by mass or more, and may be 30% by mass or less, 20% by mass or less, 10% by mass or less, or 5% by mass or less, on the basis of the total amount of the adhesive film.

The adhesive film 10, for example, can be formed by applying the thermosetting adhesive agent to a support film. In the formation of the adhesive film 10, a varnish of the thermosetting adhesive agent (an adhesive varnish) may be used. In the case of using the adhesive varnish, the adhesive film 10 can be obtained by mixing or kneading the component (A), the component (B), and the component (C), and components added as necessary in a solvent to prepare the adhesive varnish, applying the obtained adhesive varnish to the support film, and removing the solvent by heating and drying.

The support film is not particularly limited insofar as the support film is capable of withstanding the heating and drying, and for example, may be a polyester film, a polypropylene film, a polyethylene terephthalate film, a polyimide film, a polyether imide film, a polyethylene naphthalate film, a polymethyl pentene film, and the like. The support film may be a multi-layer film obtained by combining two or more types of support films, or may be a support film of which the surface is treated with a mold release agent such as a silicone-based mold release agent or a silica-based mold release agent. The thickness of the support film, for example, may be 10 to 200 μm, or 20 to 170 μm.

The mixing or kneading can be performed by suitably combining general dispersers such as a stirrer, a mortar machine, a triple roll mill, and a ball mill.

The solvent used to prepare the adhesive varnish is not limited insofar as each of the components can be homogeneously dissolved, kneaded, or dispersed in the solvent, and a known solvent of the related art can be used. Examples of such a solvent include a ketone-based solvent such as acetone, methyl ethyl ketone, methyl isobutyl ketone, and cyclohexanone, dimethyl formamide, dimethyl acetamide, N-methyl pyrrolidone, toluene, xylene, and the like. The solvent, from the viewpoint of a drying rate and a price, may be the methyl ethyl ketone or the cyclohexanone.

As a method for applying the adhesive varnish to the support film, a known method can be used, and for example, a knife coating method, a roll coating method, a spray coating method, a gravure coating method, a bar coating method, a curtain coating method, and the like can be used. A heating and drying condition is not particularly limited insofar as the solvent used is sufficiently volatilized in the condition, and for example, may be at 50 to 150° C. for 1 to 30 minutes.

The thickness of the adhesive film 10, for example, may be 1 μm or more, 3 μm or more, 20 μm or more, 25 μm or more, 30 μm or more, 35 μm or more, 40 μm or more, 50 μm or more, 60 μm or more, 70 μm or more, or 80 μm or more, and may be 200 μm or less, 150 μm or less, 120 μm or less, 100 μm or less, 80 μm or less, or 60 μm or less.

In a case where the adhesive film 10 is an adhesive film for FOD, in order to suitably embed the entire semiconductor chip (for example, controller chip), the thickness of the adhesive film 10, for example, may be 40 to 200 μm, 60 to 150 μm, or 80 to 120 μm. In a case where the adhesive film 10 is an adhesive film for FOW, in order to embed the wire such that the wire is not in contact with the semiconductor chip, the thickness of the adhesive film 10, for example, may be 20 to 120 μm, 25 to 80 μm, or 30 to 60 μm.

The adhesive film 10 prepared on the support film, from the viewpoint of preventing damage or contamination, may include a cover film on the surface of the adhesive film on a side opposite to the support film. Examples of the cover film include a polyethylene film, a polypropylene film, a film of which the surface is treated with a peeling agent, and the like. The thickness of the cover film, for example, may be 15 to 200 μm, or 30 to 170 μm.

The adhesive film 10, for example, can be used as a protective sheet for protecting the back surface of a semiconductor element (a semiconductor chip) of a flip chip-type semiconductor device, or a sealing sheet for sealing between the surface of the semiconductor element (the semiconductor chip) of the flip chip-type semiconductor device and an adherend.

### [Integrated Dicing/Die Bonding Film]

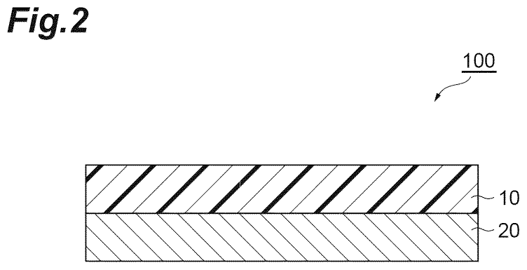

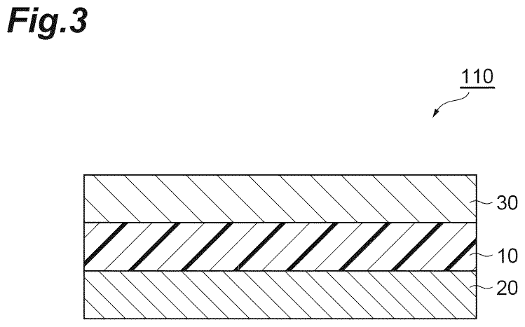

FIG. 2 and FIG. 3 are schematic cross-sectional views illustrating one embodiment of a stacked body including the adhesive film. The adhesive film 10 may be supplied in the form of the stacked body illustrated in FIG. 2 or FIG. 3. A stacked body 100 illustrated in FIG. 2 includes a base material layer 20, and the adhesive film 10 provided on the base material layer 20. A stacked body 110 illustrated in FIG. 3 further includes a protective film 30 provided on the surface of the adhesive film 10 on a side opposite to the base material layer 20, in addition to the constituents of the stacked body 100.

The base material layer 20 may be the same resin film as the support film. The thickness of the base material layer 20, for example, may be 10 to 200 μm, or 20 to 170 μm.

The base material layer 20 may be a dicing film. A stacked body of which the base material layer 20 is the dicing film can be used as an integrated dicing/die bonding film. The integrated dicing/die bonding film may be in the shape of a film, a sheet, or a tape.

Examples of the dicing film include a resin film such as a polytetrafluoroethylene film, a polyethylene terephthalate film, a polyethylene film, a polypropylene film, a polymethyl pentene film, and a polyimide film. The dicing film, as necessary, may be a resin film of which the surface is treated by primer application, a UV treatment, a corona discharge treatment, a grinding treatment, and an etching treatment. The dicing film may have adherence. The dicing film having adherence, for example, may be a resin film to which adherence is imparted, or a stacked film including a resin film, and an adhesive layer provided on one surface thereof. The adhesive layer can be formed from a non-ultraviolet curable or ultraviolet curable adhesive agent. The non-ultraviolet curable adhesive agent is a pressure-sensitive adhesive agent exhibiting constant adherence by pressurization in a short time. The ultraviolet curable adhesive agent is an adhesive agent of which the adherence decreases by the irradiation of an ultraviolet ray. The thickness of the adhesive layer can be suitably set in accordance with the shape, the dimension of the semiconductor device, and for example, may be 1 to 100 μm, 5 to 70 μm, or 10 to 40 μm. The thickness of the base material layer 20 that is the dicing film, from the viewpoint of an economic efficiency and the handleability of the film, may be 60 to 150 μm, or 70 to 130 μm.

The protective film 30 may be the same resin film as the cover film. The thickness of the protective film 30, for example, may be 15 to 200 μm, or 30 to 170 μm.

### [Semiconductor Device and Method for Producing the Same]

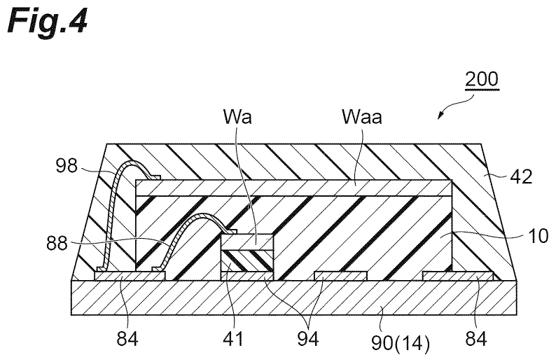

FIG. 4 is a schematic cross-sectional view illustrating one embodiment of a semiconductor device, and illustrates an example of the semiconductor device produced by using the adhesive film. A semiconductor device 200 illustrated in FIG. 4 is mainly composed of a substrate 14, a first semiconductor chip Wa and a second semiconductor chip Waa mounted on the substrate 14, a sealing layer 42 sealing the second semiconductor chip Waa, and the adhesive film 10 causing the second semiconductor chip Waa to adhere to the substrate 14. The substrate 14 includes an organic substrate 90, and circuit patterns 84 and 94 provided on the organic substrate 90. The first semiconductor chip Wa adheres to the substrate 14 by an adhesive agent 41. A first wire 88 is connected to the first semiconductor chip Wa, and the first semiconductor chip Wa is electrically connected to the circuit pattern 84 via the first wire 88. The entire first semiconductor chip Wa and the entire first wire 88 are embedded in the adhesive film 10. A second wire 98 is connected to the second semiconductor chip Waa, and the second semiconductor chip Waa is electrically connected to the circuit pattern 84 via the second wire 98. The entire second semiconductor chip Waa and the entire second wire 98 are embedded in the sealing layer 42.

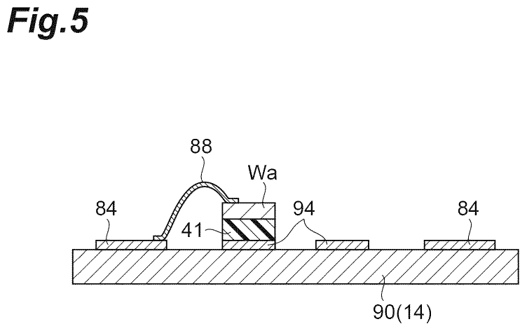

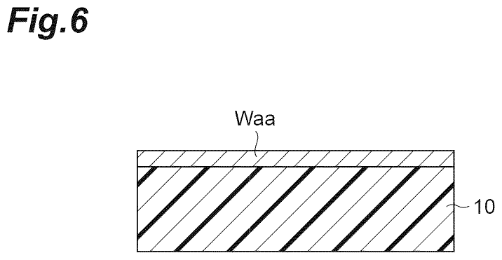

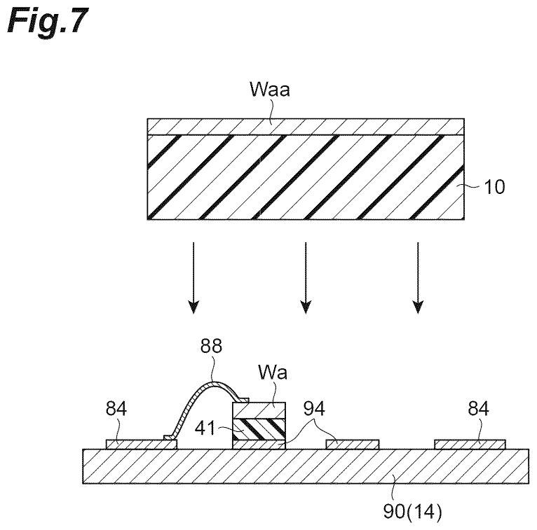

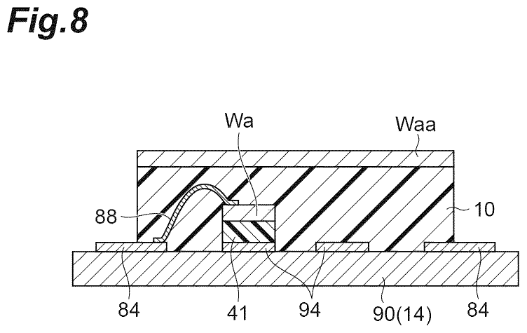

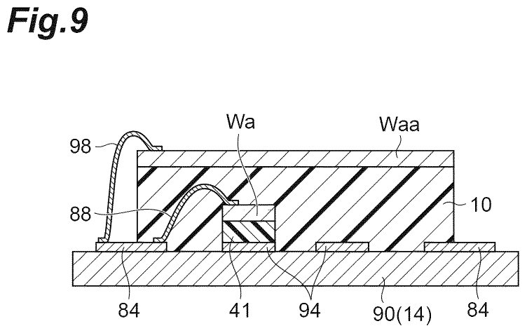

FIG. 5, FIG. 6, FIG. 7, FIG. 8, and FIG. 9 are operation flow charts illustrating one embodiment of a method for producing a semiconductor device, and are operation flow charts illustrating an example of a method for producing the semiconductor device 200 illustrated in FIG. 4. The method illustrated in FIGS. 5 to 9 includes causing the first semiconductor chip Wa to adhere to the substrate 14 via the adhesive agent 41, providing the first wire 88 connecting the first semiconductor chip Wa and the substrate 14 (the circuit pattern 84), preparing a chip with an adhesive agent including the second semiconductor chip Wbb and the adhesive film 10 attached thereto, crimping the chip with an adhesive agent to the substrate 14 to cause the second semiconductor chip Waa to adhere to the substrate 14 such that the first semiconductor chip Wa and the first wire 88 are embedded by the adhesive film 10, and providing the second wire 98 connecting the second semiconductor chip Waa and the substrate 14 (the circuit pattern 84). After that, by forming the sealing layer 44, it is possible to obtain the semiconductor device 200 illustrated in FIG. 4.

The thickness of the first semiconductor chip Wa may be 10 to 170 μm. The first semiconductor chip Wa may be a controller chip for driving the semiconductor device 200. The first semiconductor chip Wa may be a flip chip-type chip. The size of the first semiconductor chip Wa is generally less than or equal to the size of the second semiconductor chip Waa. The adhesive agent 41 interposed between the first semiconductor chip Wa and the substrate 14 may be a known adhesive agent for a semiconductor that is used in the corresponding field.

As illustrated in FIG. 5, the substrate 14 (the circuit pattern 84) and the first semiconductor chip Wa are electrically connected via the first wire 88. The first wire 88 connecting the first semiconductor chip Wa and the substrate 14 (the circuit pattern 84), for example, may be a gold wire, an aluminum wire, or a copper wire. A heating temperature for the connection of the first wire 88 may be in a range of 80 to 250° C., or 80 to 220° C. A heating time for the connection of the first wire 88 may be several seconds to several minutes. In order for the connection of the first wire 88, vibrational energy due to an ultrasonic wave and crimping energy due to an applied pressure may be imparted.

The chip with an adhesive agent consisting of the second semiconductor chip Waa and the adhesive film 10, for example, can be prepared by using an integrated dicing/die bonding film having the same configuration as that of the stacked body 100 illustrated in FIG. 2. In this case, for example, the stacked body 100 (the integrated dicing/die bonding film) is stuck to one surface of a semiconductor wafer such that the adhesive film 10 is in contact with the semiconductor wafer. The surface to which the adhesive film 10 is stuck may be a circuit surface of the semiconductor wafer, or may be a back surface on the opposite side thereof. The semiconductor wafer to which the stacked body 100 (the integrated dicing/die bonding film) is stuck is divided by dicing to form the singulated second semiconductor chip Waa. Examples of the dicing include blade dicing using a rotary blade, stealth dicing in which a modified region is prepared in the semiconductor wafer by laser to expand the base material layer, and the like. The second semiconductor chip Waa is picked up together with the divided adhesive film 10. In a case where the adhesive layer of the dicing film consists of the ultraviolet curable adhesive agent, as necessary, the adhesive layer may be irradiated with an ultraviolet ray to decrease the adhesion of the adhesive layer, before picking up the second semiconductor chip Waa.

The second semiconductor chip Waa may have a width of 20 mm or less. The width of the second semiconductor chip Waa (or the length of one side) may be 3 to 15 mm, or 5 to 10 mm.

The semiconductor wafer used to form the second semiconductor chip Waa, for example, may be a thin semiconductor wafer having a thickness of 10 to 100 μm. The semiconductor wafer may be a semiconductor wafer of not only monocrystal silicon but also polycrystalline silicon, various ceramics, a compound such as gallium arsenide, and the like. The second semiconductor chip Waa may be also formed from the same semiconductor wafer.

As illustrated in FIG. 7, the chip with an adhesive agent consisting of the adhesive film 10 and second semiconductor chip Waa is placed such that the first wire 88 and the first semiconductor chip Wa are covered with the adhesive film 10. Next, as illustrated in FIG. 8, by crimping the second semiconductor chip Waa to the substrate 14, the second semiconductor chip Waa is fixed to the substrate 14. A heating temperature for crimping may be 50 to 200° C., or 100 to 150° C. In a case where the heating temperature for crimping is high, since the adhesive film 10 is softened, there is a tendency that the embeddability is improved. A crimping time may be 0.5 to 20 seconds, or 1 to 5 seconds. A pressure for crimping may be 0.01 to 5 MPa, or 0.02 to 2 MPa.

After crimping, a structure including the adhesive film 10 may be further heated to cure the adhesive film 10. A temperature and a time for curing can be suitably set by the curing temperature of the adhesive film 10, or the like. The temperature may be gradually changed. A heating temperature, for example, may be 40 to 300° C., or 60 to 200° C. A heating time, for example, may be 30 to 300 minutes.

As illustrated in FIG. 9, the substrate 14 and the second semiconductor chip Waa are electrically connected via the second wire 98. The type and the connecting method of the second wire 98 may be the same as those of the first wire 88.

After that, the sealing layer 42 sealing the circuit pattern 84, the second wire 98, and the second semiconductor chip Waa is formed by a sealing material. The sealing layer 42, for example, can be formed by a general method using a metallic mold. After the sealing layer 42 is formed, the adhesive film 10 and the sealing layer 42 may be further thermally cured by heating. In this case, a heating temperature, for example, may be 165 to 185° C., and a heating time may be approximately 0.5 to 8 hours.

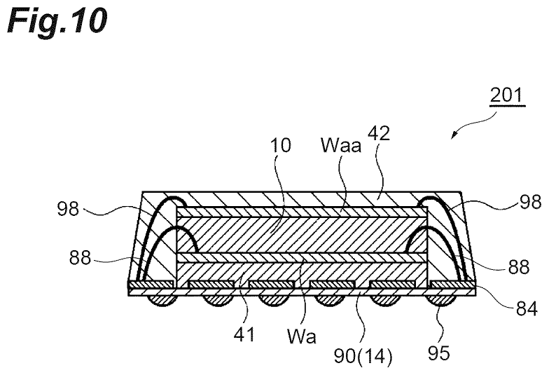

FIG. 10 is a schematic cross-sectional view illustrating another embodiment of the semiconductor device. A semiconductor device 201 is mainly composed of the substrate 14, the first semiconductor chip Wa and the second semiconductor chip Waa mounted on the substrate 14, the sealing layer 42 sealing the first semiconductor chip Wa and the second semiconductor chip Waa, and the adhesive film 10 causing the second semiconductor chip Waa to adhere to the first semiconductor chip Wa. The substrate 14 includes the organic substrate 90, the circuit patterns 84 and 94 provided on the organic substrate 90, and a connecting terminal 95 provided on the surface of the organic substrate 90 on a side opposite to the circuit patterns 84 and 94. The first semiconductor chip Wa adheres to the substrate 14 by the adhesive agent 41. The first wire 88 is connected to the first semiconductor chip Wa, and the first semiconductor chip Wa is electrically connected to the circuit pattern 84 via the first wire 88. A part of the first wire 88 is embedded in the adhesive film 10. The second wire 98 is connected to the second semiconductor chip Waa, and the second semiconductor chip Waa electrically connected to the circuit pattern 84 via the second wire 98.

The semiconductor device 201 illustrated in FIG. 10 can be produced by the same method as the method for producing the semiconductor device 200 including causing the second semiconductor chip Waa to adhere to the first semiconductor chip Wa by the adhesive film 10.

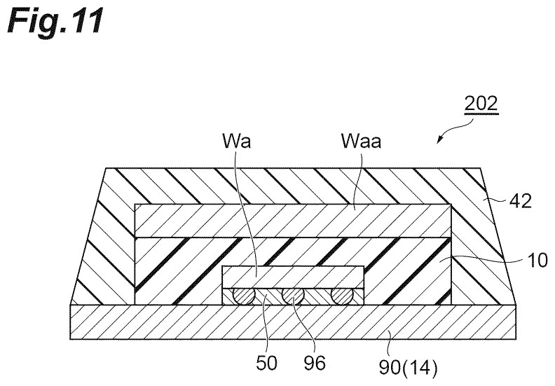

FIG. 11 is a schematic cross-sectional view illustrating another embodiment of the semiconductor device. A semiconductor device 202 is mainly composed of the substrate 14 (the organic substrate 90), the first semiconductor chip Wa and the second semiconductor chip Waa mounted on the substrate 14, the sealing layer 42 sealing the first semiconductor chip Wa and the second semiconductor chip Waa, and the adhesive film 10 causing the second semiconductor chip Waa to adhere to the substrate 14 while embedding the entire first semiconductor chip Wa. The first semiconductor chip Wa is a flip chip-type chip, and is electrically connected to the substrate 14 via a plurality of electrodes 96. Underfill 50 is filled between the first semiconductor chip Wa and the substrate 14.

### EXAMPLES

Hereinafter, the present disclosure will be described in detail, on the basis of Examples, but the present disclosure is not limited thereto.

### [Preparation of Adhesive Film]

### Examples 1 to 7 and Comparative Examples 1 to 3

### <Preparation of Adhesive Varnish>

Cyclohexanone was added to a composition consisting of a component (A) and a component (C) with product names and composition ratios (Unit: parts by mass) shown in Table 1 and Table 2, and stirred and mixed. A component (B) shown in Table 1 and Table 2 was added thereto, and stirred, and a component (D) and a component (E) shown in Table 1 and Table 2 were further added thereto, and stirred such that each component was homogeneous, and an adhesive varnish was prepared. Note that the numerical values of the component (B) and the component (C) shown in Table 1 and Table 2 indicate parts by mass of a solid content.

### Component (A): Thermosetting Resin Component

### Component (A1): Thermosetting Resin

(A1-1) N-500P-10 (product name, manufactured by DIC Corporation, an o-cresol novolac-type epoxy resin, epoxy equivalent: 204 g/eq, Softening Point: 75 to 85° C.)
(A1-2) EXA-830CRP (product name, manufactured by DIC Corporation, a liquid bisphenol F-type epoxy resin, epoxy equivalent: 159 g/eq)

### Component (A2): Curing Agent

(A2-1) MEH-7800M (product name, manufactured by MEIWA KAGAKU KOUGYOU CO., LTD, a phenyl aralkyl-type phenol resin, hydroxyl equivalent: 174 g/eq, Softening Point: 80° C.)
(A2-2) PSM-4326 (product name, manufactured by Gun Ei Chemical Industry Co., Ltd., a phenol novolac resin, hydroxyl equivalent: 105 g/eq, Softening Point: 120° C.)

### Component (B): Elastomer

### Component (B1): First Acrylic Resin

(B1-1) an acrylic resin A (an acrylic resin that is a copolymer of butyl acrylate/ethyl acrylate/ethyl methacrylate/glycidyl methacrylate/styrene, content of structural unit derived from styrene: 9% by mass (on the basis of the total structural unit), weight average molecular weight: 400000, Tg: 5° C.)

### Component (B2): Second Acrylic Resin

(B2-1) an acrylic resin B (HTR-860P-3CSP (product name), manufactured by Nagase ChemteX Corporation, an acrylic resin, weight average molecular weight: 800000, Tg: 12° C.)
(B2-2) an acrylic resin C (an acrylic resin excluding a structural unit derived from acrylonitrile from an acrylic resin of SG-P3 (product name, manufactured by Nagase ChemteX Corporation), weight average molecular weight: 600000, Tg: 12° C.)

### Component (C): Inorganic Filler

(C-1) a silica filler A (SC2050-HLG (product name), manufactured by ADMATECHS COMPANY LIMITED, a silica filler dispersion liquid, average particle size: 0.50 μm)
(C-2) a silica filler B (a silica filler dispersion liquid, average particle size: 0.18 μm)

### (D) Curing Accelerator

(D-1) 2PZ-CN (product name, manufactured by SHIKOKU CHEMICALS CORPORATION, 1-cyanoethyl-2-phenyl imidazole)

### <Preparation of Adhesive Film>

The prepared adhesive varnish was filtered with a 100-mesh filter, and subjected to vacuum deaeration. As a base material layer, a polyethylene terephthalate (PET) film with a thickness of 38 μm, which was subjected to a mold release treatment, was prepared, and the adhesive varnish after vacuum deaeration was applied onto the PET film. The applied adhesive varnish was heated and dried in two stages such as at 90° C. for 5 minutes, and then, at 140° C. for 5 minutes to obtain adhesive films of Examples 1 to 7 and Comparative Examples 1 to 3, which were in a stage B state. In the adhesive film, the applied amount of the adhesive varnish was adjusted such that the thickness was 60 μm. Two of the obtained adhesive films with a thickness of 60 μm were prepared, and stuck to each other at 70° C. to prepare an adhesive film with a thickness of 120 μm.

### [Evaluation of Adhesive Film]

### <Measurement of Ratio of Nitrile Group to Acrylic Resin>

For the adhesive film of Example 3, an IR spectrum was measured, and PA_{CN}/PA_{CO} was calculated. First, for the adhesive film, a transmissive IR spectrum was measured by a KBr tablet method, and displayed with an absorbance on a vertical axis and a wave number (cm⁻¹) on a horizontal axis. In the measurement of the IR spectrum, FT-IR6300 (manufactured by JASCO Corporation, Light Source: a high-brightness ceramic light source, Detector: DLATGS) was used. Next, in the displayed spectrum, when a straight line connecting two points of 1650 cm⁻¹ and 1800 cm⁻¹ on the spectrum was set as a baseline, the area of an absorbance surrounded by the spectrum and the baseline was calculated as PA_{CO}. In addition, when a straight line connecting two points of 2230 cm⁻¹ and 2300 cm⁻¹ on the spectrum was set as a baseline, the area of an absorbance surrounded by the spectrum and the baseline was calculated as PA_{CN}. On the basis of the calculated PA_{CO} and PA_{CN}, PA_{CN}/PA_{CO} was obtained. Such an operation was performed a total of three times, and the average value of PA_{CN}/PA_{CO} obtained by three times of the operation was 0.014.

### <Evaluation of HAST Resistance>

A substrate for a printed wiring board (manufactured by Showa Denko Materials Co., Ltd., Product Name: MCL-E-679) was prepared in which a copper foil with a thickness of 70 μm was stacked on a glass epoxy base material. The copper surface of the substrate for a printed wiring board was etched to form a comb-shaped electrode with line/space of 40 μm/40 μm. Each of the adhesive films (5 mm×12 mm) of Examples 1 to 7 and Comparative Examples 1 to 3, having a thickness of 120 μm, was stuck onto the substrate, on which the comb-shaped electrode is formed, at a temperature of 120° C., a time for 2 seconds, and a pressure of 0.2 MPa. Next, in a reduced-pressure drier, heating was performed in a condition of a temperature of 90° C., a time for 1 hour, and a pressure of 0.6 MPa, and then, heating was further performed in a condition of a temperature of 130° C., a time for 1 hour, and a pressure of 0.6 MPa to prepare an evaluation substrate. The evaluation substrate was exposed under a condition of 130° C. and 85% RH in a state where a DC voltage of 13.2 V was applied, and a resistance value between lines was measured by applying a voltage. In the measurement of the resistance value, the number of times when a decrease in the resistance value of two or more digits was observed was counted, and a time from the start of the test to when the 50th decrease in the resistance value was observed was evaluated in accordance with the following criteria. Results are shown in Table 1 and Table 2.

A: the time from the start of the test to when the 50th decrease in the resistance value was observed was longer than 100 hours.

B: the time from the start of the test to when the 50th decrease in the resistance value was observed was longer than 50 hours and 100 hours or shorter.

C: the time from the start of the test to when the 50th decrease in the resistance value was observed was 50 hours or shorter.

### <Evaluation of Adhesive Force>

(Preparation of Semiconductor Chip with Adhesive Film)

A dicing film (manufactured by Showa Denko Materials Co., Ltd., a thickness of 100 μm) including a resin film and an adhesive layer was prepared, and each of the prepared adhesive films (a thickness of 120 μm) of Examples 1 to 7 and Comparative Examples 1 to 3 was stuck thereto to prepare an integrated dicing/die bonding film including the dicing film, and the adhesive film provided on one surface of the dicing film. Next, a semiconductor wafer (a thickness of 400 μm) was stuck onto the adhesive film side of the integrated dicing/die bonding film at a stage temperature of 70° C. Cutting was performed by dicing using a fully automatic dicing saw DFD-6361 (manufactured by DISCO Corporation) to form a semiconductor chip having a size of 2 mm×2 mm. A semiconductor chip with an adhesive film consisting of the semiconductor chip, and the adhesive film attached thereto was picked up to obtain the semiconductor chip with an adhesive film.

### (Adhesive Force to Organic Substrate (Solder Resist))

By using the obtained semiconductor chip with an adhesive film, a die shear strength after curing was measured. The semiconductor chip was thermally crimped onto a solder resist (manufactured by TAIYO HOLDINGS CO., LTD., Product Name: SR-1). As a crimping condition, a temperature was 120° C., a time was 1 second, and a pressure was 0.1 MPa. Subsequently, an evaluation sample obtained by crimping was put in a drier, heating was performed at 110° C. for 1 hour, and then, a temperature increase was performed for 30 minutes, and heating was further performed at 175° C. for 5 hours to cure the evaluation sample. Subsequently, in the cured evaluation sample, by pulling the semiconductor chip while hanging with a universal bond tester (manufactured by Nordson Advanced Technology (Japan) K.K., Product Name: Series 4000), a die shear strength after curing between the semiconductor chip and an organic substrate was measured. The die shear strength was measured in a condition of 6.7 MPa, 260° C., and a stage retention time for 20 seconds. Results are shown in Table 1 and Table 2.

### (Adhesive Force to Gold Substrate)

An adhesive force was evaluated by using a gold substrate, which is more difficult to adhere to than the organic substrate. That is, an adhesive force to the gold substrate is an evaluation method in a condition stricter than that of an adhesive force to the organic substrate (the solder resist). By using the obtained semiconductor chip with an adhesive film, a die shear strength after curing was measured. The semiconductor chip was thermally crimped onto the gold substrate. As a crimping condition, a temperature was 120° C., a time was 1 second, and a pressure was 0.1 MPa. Subsequently, an evaluation sample obtained by crimping was put in a drier, heating was performed at 110° C. for 1 hour, a temperature increase was performed for 30 minutes, and heating was further performed at 175° C. for 5 hours to cure the evaluation sample. Subsequently, in the cured evaluation sample, by pulling the semiconductor chip while hanging with a universal bond tester (manufactured by Nordson Advanced Technology (Japan) K.K., Product Name: Series 4000), a die shear strength after curing between the semiconductor chip and the gold substrate was measured. The die shear strength was measured in a condition of 6.7 MPa, 260° C., and a stage retention time for 20 seconds. Results are shown in Table 1 and Table 2. Note that in Comparative Example 1, the die shear strength is less than the measurement lower limit of the measurement device, which was unmeasurable.

TABLE 1

| | | | | | Comp. |
|---|---|---|---|---|---|
| | | | Exam. 1 | Exam. 2 | Exam. 1 |
| (A) | (A1) | (A1-1) | 15 | 15 | 15 |
| | | (A1-2) | 14 | 14 | 14 |
| | (A2) | (A2-1) | 24 | 24 | 24 |
| | | (A2-2) | — | — | — |
| (B) | (B1) | (B1-1) | 9 | 17 | — |
| | (B2) | (B2-1) | 9 | — | — |
| | | (B2-2) | — | — | 17 |
| (C) | | (C-1) | 29 | 29 | 29 |
| | | (C-2) | — | — | — |
| (D) | | (D-1) | 0.06 | 0.06 | 0.06 |

| HAST resistance | | A | A | A |
|---|---|---|---|---|
| Adhesive Force (die | Organic | 6.2 | 3.6 | 3.0 |
| shear strength, MPa) | substrate | | | |
| | Gold | 1.0 | 1.0 | NG |
| | substrate | | | |

As shown in Table 1, the adhesive films of Examples 1 and 2, containing an acrylic resin having a structural unit derived from a monomer having an aromatic ring as the elastomer, were excellent in HAST resistance, and excellent in the adhesive force, compared to the adhesive film of Comparative Example 1, not containing the acrylic resin having a structural unit derived from a monomer having an aromatic ring as the elastomer.

TABLE 2

| | | | | | | | | Comp. | Comp. |
|---|---|---|---|---|---|---|---|---|---|
| | | | Exam. 3 | Exam. 4 | Exam. 5 | Exam. 6 | Exam. 7 | Exam. 2 | Exam. 3 |
| (A) | (A1) | (A1-1) | 15 | 15 | 5 | 15 | 10 | 15 | 10 |
| | | (A1-2) | 8 | 13 | 10 | 5 | 5 | 14 | 17 |
| | (A2) | (A2-1) | 5 | 5 | 5 | 5 | 5 | 24 | — |
| | | (A2-2) | 10 | 10 | 5 | 5 | 5 | — | 12 |
| (B) | (B1) | (B1-1) | 10 | 19 | 18 | 10 | 12 | — | — |
| | (B2) | (B2-1) | 26 | 19 | 24 | 10 | 12 | 17 | 22 |
| | | (B2-2) | — | — | — | — | — | — | — |
| (C) | | (C-1) | 14 | 10 | 22 | 40 | 27 | 29 | 39 |
| | | (C-2) | 13 | 10 | 10 | 10 | 23 | — | — |
| (D) | | (D-1) | 0.06 | 0.06 | 0.06 | 0.06 | 0.06 | 0.06 | 0.06 |

| HAST resistance | | B | B | A | B | B | C | C |
|---|---|---|---|---|---|---|---|---|
| Adhesive Force | Gold | 4.6 | 3.3 | 3.0 | 4.3 | 3.9 | 1.0 | 1.8 |
| (MPa) | substrate | | | | | | | |

As shown in Table 2, the adhesive films of Examples 3 to 7, containing the acrylic resin having a structural unit derived from a monomer having an aromatic ring as the elastomer, were excellent in both of the HAST resistance and the adhesive force, compared to the adhesive films of Comparative Examples 2 and 3, not containing the acrylic resin having a structural unit derived from a monomer having an aromatic ring as the elastomer.

From the results described above, it was checked that the adhesive film for a semiconductor of the present disclosure is excellent in the HAST resistance and has a high adhesive force.

### REFERENCE SIGNS LIST

10: adhesive film, 14: substrate, 20: base material layer (dicing film), 30: protective film, 41: adhesive agent, 42: sealing layer, 84, 94: circuit pattern, 88: first wire, 90: organic substrate, 98: second wire, 100, 110: stacked body, 200, 201, 202: semiconductor device, Wa: first semiconductor chip, Waa: second semiconductor chip.

1. An adhesive film for a semiconductor, comprising:
a thermosetting component;
an elastomer; and
an inorganic filler,
wherein the elastomer comprises an acrylic resin having a structural unit derived from a monomer having an aromatic ring.

2. The adhesive film for a semiconductor according to claim 1, wherein the adhesive film for a semiconductor has a thickness of 60 to 150 μm.

3. (canceled)

4. The adhesive film for a semiconductor according to claim 1, wherein the adhesive film for a semiconductor has a thickness of 25 to 80 μm.

5. (canceled)

6. The adhesive film for a semiconductor according to claim 1,
wherein the elastomer further comprises an acrylic resin not having a structural unit derived from a monomer having an aromatic ring, and
a weight average molecular weight of the acrylic resin not having a structural unit derived from a monomer having an aromatic ring is 500000 or more.

7. The adhesive film for a semiconductor according to claim 1, wherein a content of the elastomer is 10 to 60% by mass, on the basis of a total amount of the adhesive film for a semiconductor.

8. The adhesive film for a semiconductor according to claim 1, wherein a content of the inorganic filler is 30 to 250 parts by mass, with respect to 100 parts by mass of the thermosetting component.

9. An integrated dicing/die bonding film, comprising:
a dicing film; and
the adhesive film for a semiconductor according to claim 1 provided on the dicing film.

10. A method for producing a semiconductor device, comprising
causing a second semiconductor chip to adhere to a substrate on which a first semiconductor chip is mounted by the adhesive film for a semiconductor according to claim 1,
wherein the first semiconductor chip is embedded by the adhesive film.

11. A method for producing a semiconductor device, comprising
causing a second semiconductor chip to adhere to a first semiconductor chip by the adhesive film for a semiconductor according to claim 1,
wherein a wire is connected to the first semiconductor chip, and
a part or all of the wire is embedded by the adhesive film.

12. The method for producing a semiconductor device according to claim 10, wherein the first semiconductor chip is a controller chip.

13. The method for producing a semiconductor device according to claim 11, wherein the first semiconductor chip is a controller chip.

14. The adhesive film for a semiconductor according to any one of claim 2,
wherein the elastomer further comprises an acrylic resin not having a structural unit derived from a monomer having an aromatic ring, and
a weight average molecular weight of the acrylic resin not having a structural unit derived from a monomer having an aromatic ring is 500000 or more.

15. The adhesive film for a semiconductor according to any one of claim 4,
wherein the elastomer further comprises an acrylic resin not having a structural unit derived from a monomer having an aromatic ring, and
a weight average molecular weight of the acrylic resin not having a structural unit derived from a monomer having an aromatic ring is 500000 or more.

16. The adhesive film for a semiconductor according to any one of claim 2, wherein a content of the elastomer is 10 to 60% by mass, on the basis of a total amount of the adhesive film for a semiconductor.

17. The adhesive film for a semiconductor according to any one of claim 4, wherein a content of the elastomer is 10 to 60% by mass, on the basis of a total amount of the adhesive film for a semiconductor.

18. The adhesive film for a semiconductor according to any one of claim 2, wherein a content of the inorganic filler is 30 to 250 parts by mass, with respect to 100 parts by mass of the thermosetting component.

19. The adhesive film for a semiconductor according to any one of claim 4, wherein a content of the inorganic filler is 30 to 250 parts by mass, with respect to 100 parts by mass of the thermosetting component.

20. A method for producing a semiconductor device, comprising
causing a second semiconductor chip to adhere to a substrate on which a first semiconductor chip is mounted by the adhesive film for a semiconductor according to claim 2,
wherein the first semiconductor chip is embedded by the adhesive film.

21. A method for producing a semiconductor device, comprising
causing a second semiconductor chip to adhere to a first semiconductor chip by the adhesive film for a semiconductor according to claim 4,
wherein a wire is connected to the first semiconductor chip, and
a part or all of the wire is embedded by the adhesive film.
